(19) United States
(12) Patent Application Publication
(10) Pub. No.: US 2008/0197464 A1
(43) Pub. Date: Aug. 21, 2008

(54) Integrated Circuit Device Package with an Additional Contact Pad, a Lead Frame and an Electronic Device

(75) Inventor: Peter Adrianus Jacbus Dirks, Nijmegen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/817,020

(22) PCT Filed: Feb. 15, 2006
(86) PCT No.: PCT/IB06/50494

§ 371 Date: Aug. 23, 2007

(30) Foreign Application Priority Data
Feb. 23, 2005 (EP) 05101382.9

(51) Int. Cl. H01L 23/495

(52) U.S. Cl. 257/676; 257/E23.031

(57) ABSTRACT

A semiconductor device package (10) comprising: a die attach pad (12); a plurality of contact pads provided in at least four rows at least two tie bars (18) for supporting the die attach pad; a semiconductor die mounted on the top surface of the die attach pad (12) and having bond pads formed thereon; a plurality of electrical connections between selected ones of the bond pads (44) and corresponding ones of the contact pads; an encapsulation (28) leaving the bottom surface of the die attach pad and the bottom surface of the contact pads exposed; characterized by an additional contact pad (30) formed by replacing one of the tie bars (18), with the additional contact pad leaving at least one tie bar for supporting the die attach pad (12).

The present invention relates to an integrated circuit device package according to the preamble of claim 1.

The present invention also relates to a leadframe that is used to manufacture an integrated circuit device package.

Furthermore, the present invention relates to an electronic device comprising an electronic carrier, such as a printed circuit board, on which a semiconductor device package is connected.

A package, as described in the first paragraph, is known for example from U.S. Pat. No. 6,229,200, which discloses leadless plastic chip carriers that are formed from a matrix of leadframes and have a flexible configuration. A lead frame matrix is applied, which integrates a plurality of contact pads and die attach pads in order to allow production in large series.

The problem with these prior art packages is their relatively large overall size. There is an ever-increasing need for smaller packages, since they are cheaper to produce and enable to provide more functions within a pre-determined volume of an electronic device.

It is an object of the present invention to provide an integrated circuit device package according to the preamble of claim 1 that has a smaller size and thus provides a cheaper package in comparison with the prior art packages.

It is another object of the present invention to provide an integrated circuit device package that has improved connectivity properties as regards the connection to an electronic carrier, such as a printed circuit board.

It is yet another object of the present invention to provide an integrated circuit device package that enables a more reliable connection of the package with an electronic carrier.

According to the present invention, these objects are achieved by the technical measure as described in the characterizing portion of claim 1. Package size is mainly determined by the amount of contact pads (sometimes also referred to as contact pins) in the respective rows of contact pads in the package. According to the invention, an additional contact pad that replaces one of the tie bars allows reducing the number of contact pads in the respective rows. Usually, a package, see for example the package described in U.S. Pat. No. 6,229,200, has four tie bars that extend from the die attach pad and are connected to a lead frame matrix in the first stages of manufacturing. The lead frame matrix integrates a plurality of contact pads and die attach pads in order to allow production in large series. The function of the tie bars is to support the die attach pad until the so-called singulation step in the manufacturing process, in which step the individual packages are separated from the lead frame matrix. The present invention is based on the insight that the number of tie bars can be reduced without losing the supportive function of the remaining bars.

The additional contact pad also provides improved connectivity properties as regards the connection of the package to an electronic carrier, such as a printed circuit board. It could be stated that, on the one hand, the invention enables smaller package sizes at a given number of contact pads. On the other hand, more contact pads are possible at a given package size. Particularly, in the type of packages to which the invention relates, the number of available contact pads cannot be chosen freely, e.g. from any number between ±10 and ±100, but only stepwise. A 6×6 mm package has 48 pins, and a 7×7 mm package has 56 pins, and a 8×8 mm package has for instance 64 pins. The invention now leads to an intermediate size; e.g. the 6×6 package may accommodate up to 51 pins. Thus, for a chip with 50 bonding pads, now a 6×6 mm package can be used instead of the 7×7 mm package needed in the prior art.

Another consequence of the additional contact pad is that upon connecting the package to an electronic carrier the additional contact pad allows a more reliable connection. This is caused by the fact that the additional contact pad is disposed besides two rows of regular contact pads in the proximity of a corner of the package. It has been observed that this type of package, particularly the QFN package, may be sensitive to warpage when soldered to a carrier, e.g. printed circuit board. This appears to be the consequence of thermal cycling. Particularly the corners are prone to bending. As a result, the solder connection to the contact pads adjacent the corner may fail, thereby limiting lifetime. The additional contact pads in the corner provide a mechanically stronger connection between the corners, and thereby a barrier against warpage. This is particularly the case as these corner contact pads are at least partially oriented radially, e.g. on the line from corner to center of the package. Additionally, the corner pads may be of larger size. Thus, an additional connection point is created at a favorable location, resulting in a connection to the electronic carrier that is more reliable.

The additional contact pad can be created during the manufacturing process, e.g. by interrupting the connection between a tie bar and the die attach pad. Preferably, however, the additional contact pad will already be incorporated in the design of the corresponding lead frame matrix without the need of altering one of the tie bars.

In an advantageous embodiment of the present invention, a part of the encapsulation is disposed between an outer edge of the additional contact pad and the corresponding corner of the package. With this measure it is possible to prevent the formation of burrs at this outer edge during sawing the individual packages from the lead frame matrix (singulation). By leaving a small amount of encapsulation material between a corner of the package and the outer edge of the additional contact pad, any sawing in the corner area takes place within this encapsulation material only. It is known that such burrs can deteriorate the connection between the package and an underlying carrier. Such burrs also cause difficult handling during testing and assembly processes.

Another advantageous embodiment of the present invention is characterized by two additional contact pads formed by replacing two tie bars by said additional contact pads, wherein two further tie bars are provided extending from the die attach pad towards diagonally opposed corners of the package. This results in two additional contact pads, allowing the number of regular contact pads disposed in the rows to be reduced even more. Moreover, two tie bars extending from the die attach pad towards diagonally opposed corners of the package will sufficiently support the die attach pad during manufacturing of the package. Upon connecting the package according to this embodiment to an electronic carrier, an additional advantage is that warpage of the package can be prevented or at least reduced by the presence of two additional connection points. Warpage between the package and an electronic carrier arises due to temperature cycles that are imposed on a certain electronic device exhibiting differences in linear thermal expansion between the different components, e.g. between the package and the printed circuit board. The two additional connection points disposed in the proximity of two diagonally opposed corners of the package will reduce the risk of warpage between the package and an electronic carrier. In contrast, the regular tie bars in this respect do not provide any additional connection points.

In another advantageous embodiment of the present invention, the distance between the additional contact pad and an adjacent contact pad is at least equal to the distance between two adjacent contact pads in a row. This measure reduces the risk that a solder bump or another type of contact material disposed respectively at the additional contact pad and an adjacent contact pad accidentally interconnect during the connection of the package to an electronic carrier. Such an accidental interconnection would cause an unwanted short-circuit.

In yet another advantageous embodiment of the present invention, the exposed bottom surface of the additional contact pads is larger than the exposed bottom surface of the contact pad in a row. This is advantageous since it will improve the reliability of the connection between this contact pad and an electronic carrier. Given the outline of the lead frame, that is suited to manufacture a package according to the present invention, in general there will be sufficient space to make the additional bond pads larger than the regular bond pads.

According to the invention it is advantageous that the electrical connections comprise wires that are bonded between the bond pads and the contact pads or between the bond pads and the die attach pad. Wire bonding is a well known and reliable method of establishing the electrical connections within a package.

The invention will be further explained herein below with reference to the accompanying drawings, in which:

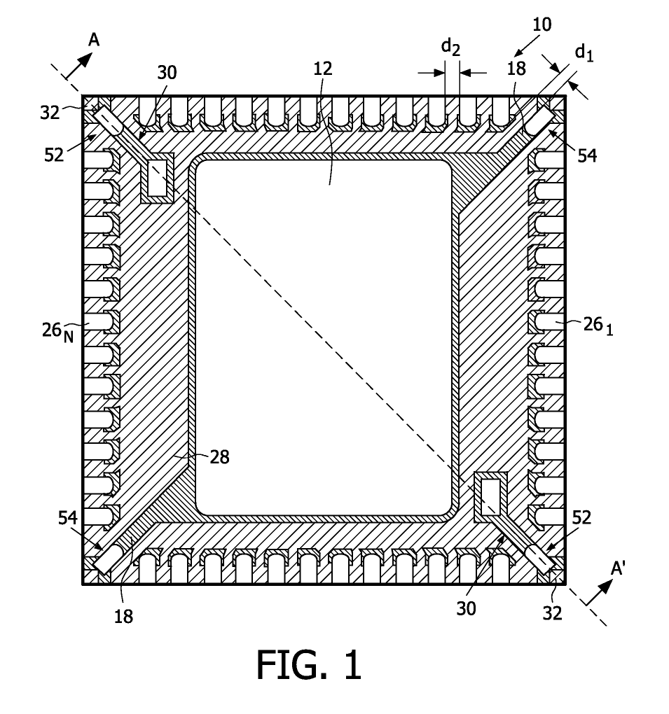

FIG. 1 shows a schematic view of the bottom surface of a semiconductor device package according to a preferred embodiment of the invention;

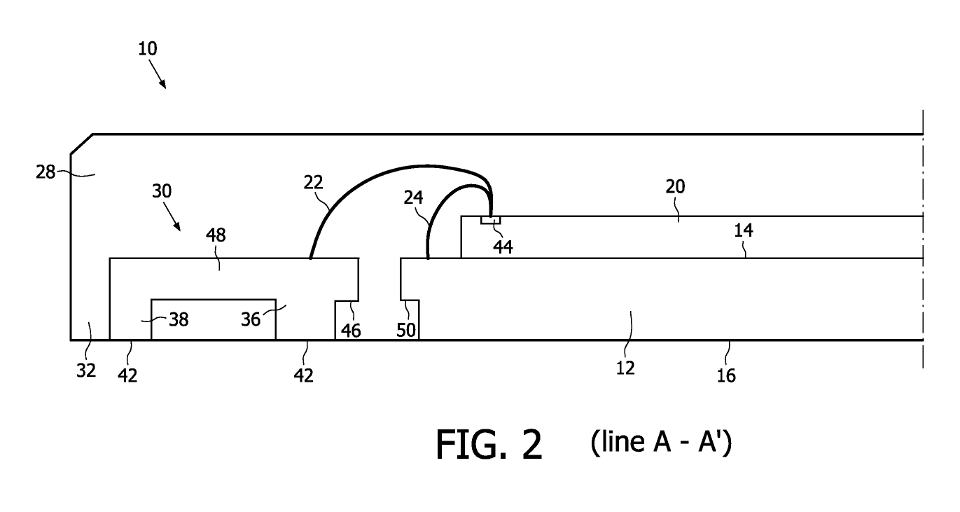

FIG. 2 shows a cross-sectional view along line A-A′ in FIG. 1 (left part);

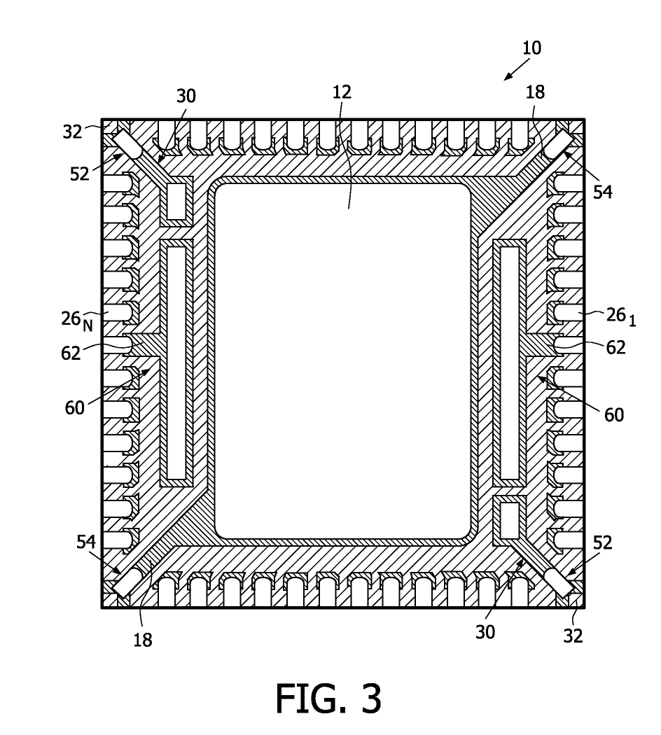

FIG. 3 shows a schematic view of the bottom surface of a semiconductor device package according to another preferred embodiment of the invention.

It should be noted first that FIG. 1 schematically shows the exposed bottom surfaces, represented by the non-hatched areas, parts filled with encapsulation material, represented by areas hatched from bottom left to top right, and the half-etched parts represented by the areas hatched from top left to bottom right, respectively. The latter parts one normally will not be able to see when looking at the bottom surface (one will see encapsulation material instead). With respect to FIG. 2, it should be noted that only the left half of the package is shown in cross-section, since the package is symmetrical with respect to line A-A′.

Referring now to FIGS. 1 and 2, a semiconductor device package 10 with a substantially rectangular shape is shown. The package comprises a die attach pad 12 having a top surface 14 and an exposed bottom surface 16, two tie bars 18 extending from the die attach pad 12 towards diagonally opposed corners of the package, and a plurality of contact pads 26₁-26ₙ provided in four rows that correspond to the rectangular shape of the package. Furthermore (see FIG. 2), the package 10 comprises a semiconductor die 20 mounted on the top surface 14 of the die attach pad and having bonding pads 44 formed thereon, a plurality of electrical connections 22,24 between selected ones of the bond pads 44 and corresponding ones of the contact pads 26₁-26ₙ. An encapsulation 28 encapsulates the semiconductor die 20, the top surface 14 of the die attach-pad 12, the electrical connections 22,24, the top surface of the tie bars 18 and the top surfaces of the contact pads, and leaves the bottom surface 16 of the die attach pad 12 and the bottom surface of the contact pads exposed.

As is shown in FIG. 1, two additional contact pads 30 are formed by replacing two tie bars by such additional contact pads (as compared to regular packages with four tie bars). In the preferred embodiment shown in FIG. 1, two tie bars 18 are present to provide the necessary support for the die attach pad during manufacturing of the package. According to the invention, it is also possible to have three additional contact pads, thus leaving one tie bar only. Alternatively, one can replace just one tie bar by an additional contact pad, thus leaving three tie bars.

The additional contact pads 30 allow reducing the number of contact pads in the respective rows. Since package size is mainly determined by the number of contact pads provided in the rows, the additional contact pads allow a smaller package size. Alternatively, at a certain given package size, the number of contact pads in the package increases. The die attach pad 12, the tie bars 18 and the contact pads 30, 26₁-26ₙ are all made from conductive material (see description of typical design flow for a lead frame design below).

Before any electrical connections are made, the contact pads 30, 26₁-26ₙ are electrically isolated from each other and from the die attach pad 12.

FIG. 2 shows the electrical connections 22,24 in more detail. They comprise wire bonds that are formed between bond pads 44 on the semiconductor die 20 and the die attach pad 12 or the additional contact pads 30, respectively. Although not shown in the FIGS. 1 and 2, logically there are also wire bonds between bond pads 44 and the regular bond pads 26₁-26ₙ.

Furthermore, FIG. 2 shows that each additional contact pad 30 comprises an exposed bottom surface 42, a wire bond part 36 and a connective part 38 for a reliable connection to an electronic carrier (not shown). The wire bond part 36 immediately adjacent to the die attach pad is necessary to reduce the length of the electrical connection (wire) 22 (see FIG. 2). If the wire length is too large, the resistance of the connection will be too large. In between both parts 36,38, a half-etched part 48 is provided. Another half-etched part 46 is provided at the opposite side of wire bond part 36. The die attach pad 12 also comprises a half-etched part 50.

A part 32 of the encapsulation is disposed between an outer edge 52 of the additional contact pad 30 and the corner of the package (see both FIGS. 1 and 2). This part 32 makes sure that, during the singulation step, any sawing in the corner area takes place within this encapsulation material only, which prevents the formation of burrs at the outer edge of the contact pad. It is known that such burrs can deteriorate the connection between the package and an electronic carrier.

In FIG. 1, the shortest distance d₁ between additional contact pad 30 and an adjacent contact pad and the distance d₂ between two adjacent contact pads in a row are illustrated.

The distance d₁ is at least equal to the distance d₂, which reduces the risk that a solder bump or another type of contact material that is disposed respectively at the additional contact pad and an adjacent contact pad accidentally interconnect during the connection of the package to an electronic carrier.

Although not illustrated in FIG. 1, preferably the area of the exposed bottom surface of the additional contact pad 30 is larger than that of the regular contact pads. This will improve the reliability of the connection between this contact pad and an underlying electronic carrier. FIG. 1 shows a part 52 of the additional contact pad 30, that provides an additional connection point in this respect. For a better connection, part 52 in fact is made as large as possible, given the requirement with respect to the distance to neighboring contact pads as illustrated in the previous paragraph. In this respect, part 52 preferably has a substantially rectangular shape. Both tie bars also comprise a part 54 that is exposed and possibly acts as an additional connection point. Preferably, however, only parts 52 are used as an additional connection point upon connecting the package to an electronic carrier. The additional connection points are advantageous with respect to preventing warpage of a package that is connected to an electronic carrier, said warpage being due to differences in linear thermal expansion.

FIG. 3 shows a schematic view of the bottom surface of a semiconductor device package according to another preferred embodiment of the invention. Besides the additional contact pads 30 and other components as shown in FIGS. 1 and 2, two strips 60 can be seen, that are disposed between the die attach pad 12 and a corresponding row of contact pads. Each strip comprises at least one lateral part 62 that is connected to at least one of the contact pads in the row. The strip allows bond pads situated at various locations on the semiconductor die 20 adjacent to the strip to be connected to said strip, e.g. by means of wires 22. Via lateral part 62 these connections are all directly linked to a corresponding contact pad. This means that bond pads 44 at various locations on the semiconductor die 20 are directly connected to one contact pad only, which bond pads otherwise would have to be connected to several contact pads in a corresponding row. Consequently, the strip 62 allows reducing the number of contact pads and thus reduces package size and cost.

With the embodiment according to FIG. 3, it was found that a 6×6 mm package provided with 50 contact pads could be used, while normally a 7×7 mm package provided with 56 contact pads was needed for the same semiconductor die. The number of 50 contact pads could be obtained by applying two additional contact pads disposed in two corners of the package that normally contained 4×12=48 contact pads.

Typically, the total number of contact pads for a package according to the invention is between 10-100, more preferably between 30-70. Although it is described as comprising one semiconductor die only, the package according to the invention is very well suited to be applied for so-called chip on chip packages, as described in for example WO-A 2004/057668. In such a chip-on-chip package, the connection from the bonding pads of the die to the contact pads may, in one embodiment, be constituted by a first connection from bonding pad to the second chip, an interconnect on the second chip and a second connection from chips to contact pad. In this embodiment, this second chip has a larger surface area than the semiconductor die on the die pad. The second chip may be an integrated circuit, an image sensor, but also a passive chip, e.g. a network of passive components, or a peripheral chip comprising a plurality of independent circuit portions between selected ones of the bonding pads and corresponding ones of the contact pads, such as ESD protection. Also packages comprising more components than just one or a few semiconductor dies (system in package) will benefit from the present invention.

Possible applications for packages according to the invention are as packages for power management semiconductors, or more generally speaking, semiconductors that produce relatively much heat.

Typically, the invention is suited to be applied with so-called QFN (quad flat no lead) packages. Sometimes these packages are referred to as HVQFN, MLF, LPCC, DQFN or MCP packages. However, it is conceivable to apply the invention for so-called QFP packages as well. In that case the additional contact pad will be an additional lead that extends from a corner of the package.

Although not illustrated, a typical design flow for a lead frame design according to an embodiment of the present invention is summarized as follows. Firstly, an appropriately dimensioned metallic, typically copper, strip is provided. Then a first, appropriately patterned mask is used to etch both upper and lower surfaces of the strip, thus providing the basic definition of the lead frame including the tie bars, die attach pad, and the (additional) contact pads. A second appropriately patterned mask may then be used to half etch the lower surfaces of the strip. The appropriately patterned strip may then be plated with, for example, a nickel-palladium NiPd protective layer. The patterned strip, i.e. lead frame, is then attached to a support tape. Having defined and prepared the lead frame, a semiconductor device package can now be produced, wherein: a semiconductor die is attached to the die attach pad; the appropriate wire bonds are made; the encapsulation is appropriately molded around the lead frame and the semiconductor die, and finally the resultant plurality of packaged semiconductor dies are singulated from the strip by accurately sawing or punching through the lead frame.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The verb “to comprise” and its conjugations does not exclude the presence of elements or steps other than those listed in any claim or the specification as a whole. The singular reference of an element does not exclude the plural reference of such elements and vice-versa. The term ‘half-etching’ as used in the context of the application generally refers to an etching treatment in which between approximately 40 and 85% of the thickness is removed, and preferably between 45 and 55%.

1. A semiconductor device package with a substantially rectangular shape comprising: a die attach pad having a top surface a and a bottom surface; a plurality of contact pads provided in at least four rows that correspond to the rectangular shape of the package, each contact pad having a top surface and a bottom surface; at least two tie bars for supporting the die attach pad until the singulation of the package during manufacturing thereof, the tie bars having a top surface and a bottom surface and extending from the die attach pad towards a corner of the package;—a semiconductor die mounted on the top surface of the die attach pad and having bond pads formed thereon; a plurality of electrical connections between selected ones of the bond pads and corresponding ones of the contact pads; an encapsulation, encapsulating the semiconductor die, the top surface of the die attach pad, the electrical connections, the top surface of the tie bars and the top surfaces of the contact pads, and leaving the bottom surface of the die attach pad and the bottom surface of the contact pads exposed; characterized by, an additional contact pad having a top surface and a bottom surface formed by replacing one of the tie bars, with the additional contact pad leaving at least one tie bar for supporting the die attach pad.

2. A semiconductor device package as claimed in claim 1, characterized in that a part of the encapsulation is disposed between an outer edge of the by said additional contact pad and the corresponding corner of the package.

3. A semiconductor device package as claimed in claim 1, characterized by two additional contact pads formed by replacing two tie bars by said additional contact pads and leaving two tie bars extending from the die attach pad towards diagonally opposed corners of the package.

4. A semiconductor device package as claimed in claim 1, characterized in that the distance between the additional contact pad and an adjacent contact pad is at least equal to the distance between two adjacent contact pads in a row.

5. A semiconductor device package as claimed in claim 1, characterized in that the exposed bottom surface of the additional contact pads is larger than the exposed bottom surfaces of the contact pads in a row.

6. A semiconductor device package as claimed in claim 1, characterized in that the electrical connections comprise wires that are bonded between the bond pad and the contact pads.

7. A lead frame that is used to manufacture a semiconductor device package as claimed in claim 1.

8. An electronic device comprising an electronic carrier, such as a printed circuit board, on which a semiconductor device package, as claimed in claim 1 is connected.
